(19) United States
(12) Patent Application Publication
(10) Pub. No.: US 2012/0238097 A1
(43) Pub. Date: Sep. 20, 2012

(54) METHOD FOR FABRICATING FINE LINE

(75) Inventors: Ru Huang, Beijing (CN); Shuangshuang Pu, Beijing (CN); Yujie Ai, Beijing (CN); Zhihua Hao, Beijing (CN); Runsheng Wang, Beijing (CN)

(73) Assignee: Peking University

(21) Appl. No.: 13/513,852

(22) PCT Filed: Sep. 29, 2011
(86) PCT No.: PCT/CN2011/080330

§ 371 Date: Jun. 4, 2012

(30) Foreign Application Priority Data
Dec. 3, 2010 (CN) 201010572032.0

(51) Int. Cl. H01L 21/311

(52) U.S. Cl. 438/694; 257/E21.249

(57) ABSTRACT

Disclosed herein is a method for fabricating a fine line, which belongs to a field of ultra-large-scale integrated circuit manufacturing technology. In the invention, three trimming mask processes are performed to effectively improve a profile of the line and greatly reduce the LER (line edge roughness) of the line. At the same time, the invention is combined with a sidewall process, so that a nano-scaled fine line can be successfully fabricated and precisely controlled to 20 nm. Thus, a nano-scaled line with an optimized LER can be fabricated over the substrate.

### CROSS-REFERENCE TO RELATED APPLICATION

The present application claims priority to Chinese Patent Application (No. 201010572032.0), filed on Dec. 3, 2010 in the State Intellectual Property Office of People's Republic of China, which is incorporated herein by reference in its entirety as if set forth herein.

### FIELD OF THE INVENTION

The invention refers to a method for reducing the line edge roughness of a nano line based on a combination of a sidewall process and a trimming process, and belongs to the field of ultra-large-scale integrated circuit manufacturing technology.

### BACKGROUND OF THE INVENTION

With the development of large scale integrated circuits, the feature size of the field effect transistors is scaled down continuously. However, the line edge roughness (LER) fabricated during the process is not scaled down by the same ratio. In addition, when the device size has entered into the sub-100 nm scale, influence on the device characteristics caused by the line edge roughness is getting worse increasingly. For instance, in a nano-scaled MOS device, LER would lead to a change of carrier mobility, an increase of off-state leakage current, a deterioration of short-channel effect and etc. In order to improve the performance of the device, it is necessary to develop a process for reducing the LER of line under a conventional photolithography technology.

In a process for manufacturing integrated circuits, a trimming process is a conventional technical means. In the trimming process, for example, the integrated circuits can be finely adjusted by using a laser process without physical contacts, thus the number of pads used in the circuits can be greatly reduced while an adjustment with high precision is achieved. As for more details about the trimming process, for example, a publication titled “A Random Trimming Approach for Obtaining High-Precision Embedded Resistors” (referring to IEEE Transactions on A Packaging, VOL. 31, NO. 1, pp. 76-81, Feb. 2008) published by Phillip Sandborn and Peter A. Sandborn can be referred, which is incorporated herein by reference in its entirety as if set forth herein.

### SUMMARY OF THE INVENTION

A purpose of the invention is to provide a process method for achieving a fine line with a reduced LER based on a combination of a sidewall process and a trimming process.

A method for fabricating a fine line includes the following steps:

(1) Fabricating a support layer for a sidewall process over a substrate.

A main purpose of this step is to fabricate a support layer used for subsequent sidewalls of silicon oxide. The support layer is made of silicon nitride film material, the thickness of the silicon nitride film determines the height of sidewalls finally formed. This step includes the following steps:

(a) Depositing a silicon nitride film over a substrate;

(b) Coating a photoresist onto the silicon nitride film, and performing a photolithography process to define a region to be used as the support layer;

(c) Performing a dry trimming process for the photoresist;

(d) Performing a dry etching process to transfer the pattern of the photoresist onto the silicon nitride film; and

(e) Removing the photoresist to obtain the support layer of silicon nitride over the substrate;

(2) Fabricating sidewalls of silicon oxide over the substrate.

A main purpose of this step is to fabricate sidewalls of silicon oxide with an improved LER as hard mask patterns for fabricating nano lines over the material of the substrate. Heights of the sidewalls of silicon oxide can be determined according to the height of the line to be finally fabricated over the material of the substrate, which can be controlled by the height of the support layer for sidewalls obtained in the step (1). The width of each of the sidewalls of silicon oxide can be determined according to the width of the line to be finally fabricated over the material of the substrate, which can be precisely controlled by the thickness of the deposited silicon oxide and the degree to which a wet trimming process on the sidewalls of silicon oxide is performed. This step mainly includes the following process flow:

(a) Depositing a silicon oxide film over the substrate material and the silicon nitride film for the support layer;

(b) Etching the silicon oxide film by using a dry etching process;

(c) Performing a wet etching process on the support layer of silicon nitride; and

(d) Performing a wet trimming process on the sidewalls of silicon oxide film.

(3) Obtaining a nano line with a significantly improved LER over the substrate material.

A main purpose of this step is to transfer the line pattern defined by the sidewalls of silicon oxide onto the substrate material, by using an anisotropic dry etching process. Since the sidewalls of silicon oxide have been passed through three trimming processes (that is, a dry trimming process for the photoresist, a wet trimming processes for the support layer of silicon nitride and the sidewalls of silicon oxide) to form a fine line, the line fabricated over the substrate material would have a significantly improved LER. This step mainly includes the following steps:

(a) Etching the substrate material by using an anisotropic dry etching process to obtain a nano-sized fine line of the material of the substrate;

(b) Removing the mask of silicon oxide on top by using a wet etching process.

In the above method, a low pressure chemical vapor deposition process is used to deposit the silicon nitride and the silicon oxide. An anisotropic dry etching process is used to etch the silicon nitride, the silicon oxide and the substrate material. A heated concentrated phosphoric acid is used to perform the wet trimming process for silicon nitride. A mixture of a hydrofluoric acid and an ammonium fluoride with mass ratio of 1:40 is used to perform the wet trimming process for silicon oxide. A buffered hydrofluoric acid is used to perform the wet etching process for silicon oxide.

In the above method, the materials of the support layer and the sidewalls can be replaced with each other. That is, in the above-mentioned fabrication method, silicon oxide can be used as a material for the support layer, and silicon nitride can be used as a material for the sidewalls.

Advantages and beneficial effects of the invention are described as follows.

In the fabrication process of an integrated circuit, the line edge roughness is originated from a photoresist that is used as a mask. Since molecule particles of the photoresist are relatively large, after a series of photolithography and etching processes, the line edge roughness will be transferred to the finally fabricated patterns, as shown in FIG. 2. Considering a problem that the LER has a serious impact on the device characteristics after the device enters into the nanometer scale, the present invention is now proposing a process method for fabricating a fine line with a reduced LER based on a combination of a sidewall process and a trimming process. The LER of nanometer-scaled sidewalls of silicon nitride fabricated by this method is improved greatly, so a purpose of fabricating a nano line with a reduced LER on the substrate is achieved. Further, the width of the line fabricated by this method can be precisely controlled to 20 nm according to the thickness of each of the sidewalls and the degree to which a wet trimming process on the sidewalls of silicon oxide is performed, as shown in FIG. 3. Thus, a nanometer-scaled line with an optimized LER can be fabricated over the substrate material.

### BRIEF DESCRIPTION OF THE DRAWINGS

FIG. 1(a)-1(i) are schematic views showing processes for fabricating a nano-sized fine line with a reduced LER, based on a combination of a sidewall process and a trimming process.

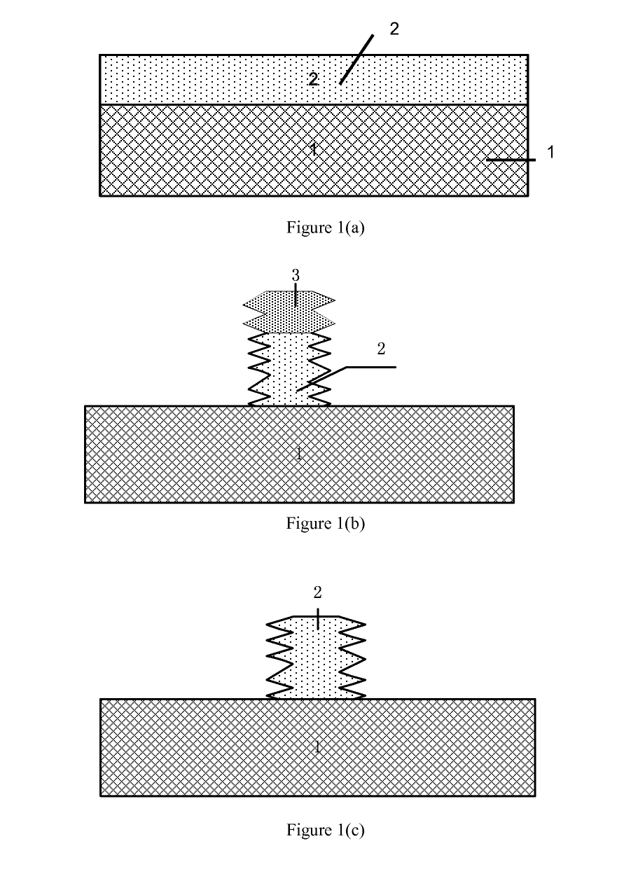

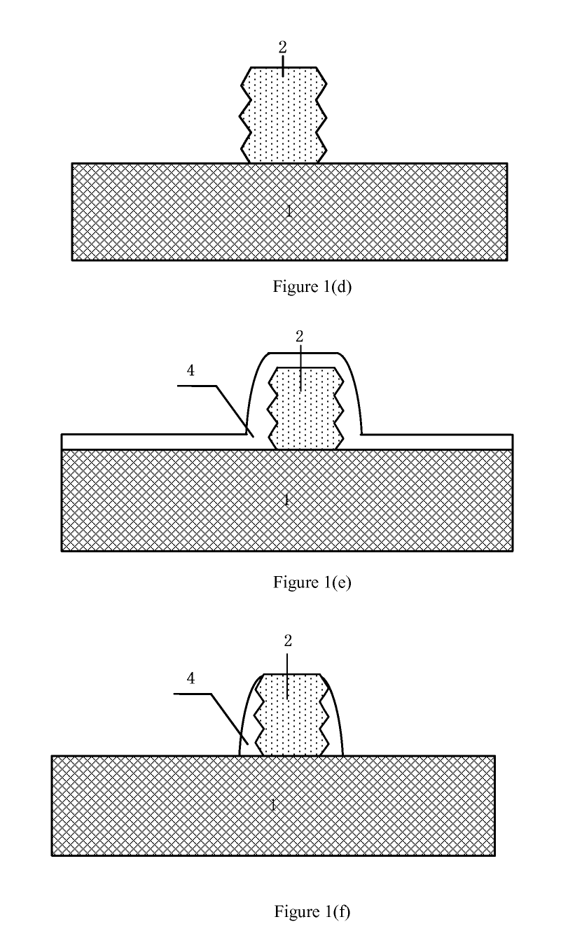

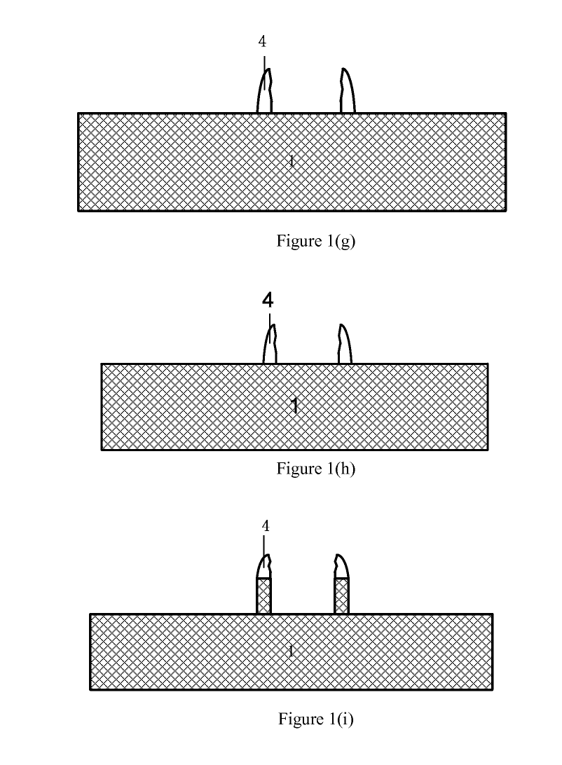

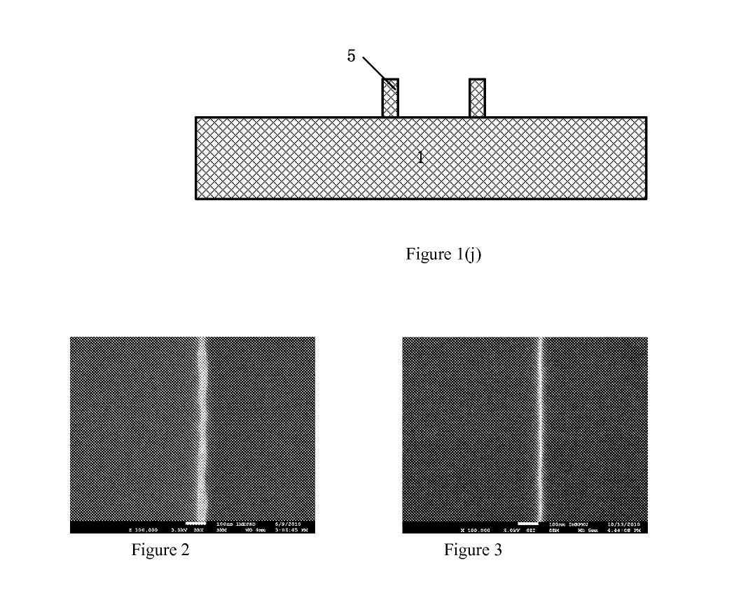

In the drawings, FIG. 1(a) shows a step of depositing a silicon nitride film over a substrate; FIG. 1(b) shows a step of obtaining the pattern of the silicon nitride film over the substrate material to be used as a support layer for subsequent sidewall process, by performing a photolithography process, performing a dry trimming process for a photoresist, and performing a dry etching process for the silicon nitride film; FIG. 1(c) shows a step of removing the photoresist; FIG. 1(d) shows a step of performing a wet trimming process for the support layer of silicon nitride; FIG. 1(e) shows a step of depositing a silicon oxide film over the substrate material and the silicon nitride film used as the support layer; FIG. 1(f) shows a step of dry etching the silicon oxide film until to the substrate; FIG. 1(g) shows a step of removing the support layer of silicon nitride by using a wet etching process so as to form sidewalls of silicon oxide; FIG. 1(h) shows a step of performing a wet trimming process for the sidewalls of silicon oxide; FIG. 1(i) shows a step of performing a dry etching process for the substrate material; and FIG. 1(j) shows a step of removing the mask of silicon oxide on top by using a wet etching process, so as to fabricate a fine line.

In the drawings, 1 denotes a substrate; 2 denotes silicon nitride; 3 denotes a photoresist; 4 denotes silicon oxide; and 5 denotes a fine line made of the substrate material.

FIG. 2 is a SEM photograph showing a nano line fabricated based on a conventional sidewall process.

FIG. 3 is a SEM photograph showing a nano line fabricated by a method based on a combination of a conventional sidewall process and a trimming mask process of the present invention.

### DETAILED DESCRIPTION OF THE EMBODIMENTS

Hereinafter, a further description of the present invention will be given through examples. It should be noted that, embodiments are disclosed for the purpose of a further understanding of the invention, and those skilled in the art of field will appreciate that various substitutions and modifications can be made without departing from the spirit and the scope of the invention and the accompanied claims. Therefore, the invention should not be limited based on the described embodiments. Rather, the scope to be protected by the invention should be limited in light of the claims.

First Embodiment

A fine line with a width of about 200 Å that has a significantly improved LER can be obtained according to the following steps.

1. As shown in FIG. 1(a), a silicon nitride film with a thickness of 1500 Å is deposited over a silicon substrate by using a low pressure chemical vapor deposition process.

2. A photoresist is coated onto the silicon nitride film, and a photolithography process is performed to define a region to be used as a sidewall support layer. Next, an isotropic trimming process by using oxygen plasma is performed on the photoresist by 200 Å. The silicon nitride film is etched by 1500 Å through an anisotropic dry etching process, so that the pattern of the photoresist can be transferred onto the material of the silicon nitride film, as shown in FIG. 1(b).

3. As shown in FIG. 1(c), the photoresist is removed.

4. As shown in FIG. 1(d), a trimming process is performed on the support layer of silicon nitride by 200 Å through a heated (170° C.) concentrated phosphoric acid.

5. As shown in FIG. 1(e), a silicon oxide film with a thickness of 400 Å is deposited over the silicon substrate and the silicon nitride film used as the support layer, by using a low pressure chemical vapor deposition process.

6. As shown in FIG. 1(f), the silicon oxide film is etched by 400 Å through an anisotropic dry etching process.

7. As shown in FIG. 1(g), the support layer of silicon nitride is eroded by 1500 Å through a heated (170° C.) concentrated phosphoric acid.

8. As shown in FIG. 1(h), a wet trimming process by using a hydrofluoric acid and an ammonium fluoride with mass ration of 1:40 is performed on the silicon oxide film by 100 Å.

9. As shown in FIG. 1(i), the silicon substrate is etched by 3000 Å through an anisotropic dry etching process.

10. As shown in FIG. 1(j), the mask of silicon oxide on top is eroded through a buffered hydrofluoric acid, so as to obtain a fine line with a width of 200 Å.

### Second Embodiment

A silicon oxide material is used for the support layer, and a silicon nitride material is used for sidewalls. A fine line with a width of about 200 Å that has a significantly improved LER can be obtained according to the following steps.

1. A silicon oxide film with a thickness of 1500 Å is deposited over a silicon substrate by using a low pressure chemical vapor deposition process.

2. A photoresist is coated onto the silicon oxide film, and a photolithography process is performed to define a region to be used as a sidewall support layer. Then, an isotropic trimming process by using oxygen plasma is performed on the photoresist by 200 Å. The silicon oxide film is etched by 1500 Å through an anisotropic dry etching process, so that the pattern of the photoresist can be transferred onto the material of the silicon oxide film.

3. The photoresist is removed.

4. A wet trimming process by using a hydrofluoric acid and an ammonium fluoride with mass ratio of 1:40 is performed on the support layer of silicon oxide by 200 Å.

5. A silicon nitride film with a thickness of 400 Å is deposited over the silicon substrate and the silicon oxide film used as the support layer, by using a low pressure chemical vapor deposition process.

6. The silicon nitride film is etched by 400 Å through an anisotropic dry etching process.

7. The support layer of silicon oxide is eroded by 1500 Å through a buffered hydrofluoric acid.

8. A wet trimming process by using a heated (170° C.) concentrated phosphoric acid is performed on the silicon nitride film by 100 Å.

9. The silicon substrate is etched by 3000 Å by using an anisotropic dry etching process.

10. The mask of silicon nitride on the top is eroded by a wet etching process using a heated (170° C.) concentrated phosphoric acid, so that a fine line with a width of 200 Å can be obtained.

While the present invention has disclosed preferred embodiments, the preferred embodiments are not used to limit the invention. Various changes, modifications or equivalents of the embodiments to the technical solution of the present invention can be made by those skilled in the art by using the above-mentioned methods and techniques without departing from the spirit or scope of the invention. Thus, it is intended that the present invention covers all such modifications changes, modifications or equivalents of the embodiments without departing from the spirit or scope of the invention they come within the scope of the appended claims.

1. A method for fabricating a fine line, including the following steps:
(1) fabricating a support layer for a sidewall process over a substrate, this step includes the following steps:
(a) depositing a silicon nitride film over the substrate;
(b) coating a photoresist onto the silicon nitride film, and performing a photolithography process to define a region to be used as the support layer;
(c) performing a dry trimming process for the photoresist;
(d) performing a dry etching process to transfer the pattern of the photoresist onto the silicon nitride film;
(e) removing the photoresist to fabricate the support layer of silicon nitride over the substrate;
(2) fabricating sidewalls of silicon oxide over the substrate, this step includes the following steps:
(a) depositing a silicon oxide film over the substrate and the silicon nitride film used as the support layer;
(b) etching the silicon oxide film by using a dry etching process;
(c) performing a wet etching process on the support layer of silicon nitride;
(d) performing a wet trimming process on the sidewalls of silicon oxide film; and
(3) obtaining a nano line with a significantly improved LER over the substrate material, this step includes the following steps:
(a) etching the substrate material by using an anisotropic dry etching process to form a nano line of the substrate material;
(b) removing the mask of silicon oxide on top by using a wet etching process.

2. The method according to claim 1, wherein a silicon oxide material is used for the support layer instead of the silicon nitride material, and a silicon nitride material is used for the sidewalls instead of the silicon oxide material.

3. The method according to claim 1, wherein a low pressure chemical vapor deposition process is used to deposit the silicon nitride and the silicon oxide.

4. The method according to claim 1, wherein an anisotropic dry etching process is used to etch the silicon oxide, silicon nitride and the substrate material.

5. The method according to claim 1, wherein a heated concentrated phosphoric acid is used to perform the wet trimming process on the silicon nitride; a mixed solution of hydrofluoric acid and ammonium fluoride is used to perform the wet trimming process on the silicon oxide; and a buffered hydrofluoric acid is used to perform the wet etching process on the silicon oxide.
